(19) United States
(12) Patent Application Publication
(10) Pub. No.: US 2025/0125646 A1
(43) Pub. Date: Apr. 17, 2025

(54) DISCHARGE DEVICE AND METHOD FOR CONTROLLING DISCHARGE THEREOF

(71) Applicant: SK ON CO., LTD., Seoul (KR)

(72) Inventors: So Yeon CHOI, Daejeon (KR); Dong Jae KANG, Daejeon (KR); Eun Seok KIM, Daejeon (KR); Yun Nyoung LEE, Daejeon (KR); Dong Hwa HAN, Daejeon (KR)

(21) Appl. No.: 18/814,614

(22) Filed: Aug. 26, 2024

(30) Foreign Application Priority Data
Oct. 12, 2023 (KR) 10-2023-0135769

(51) Int. Cl. H02J 7/00; H01M 10/44; H01M 10/48

(52) U.S. Cl. CPC H02J 7/007182; H01M 10/441; H01M 10/443; H01M 10/482; H01M 10/486; H02J 7/0048; H02J 7/007194

(57) ABSTRACT

The present disclosure provides a discharge device and a method for controlling discharge of the discharge device. The discharge device according to an embodiment of the present disclosure includes: a connection member configured to connect the discharge device and a secondary battery; a discharge module configured to discharge the secondary battery connected thereto through the connection member; and a control module configured to control the discharge module so as to primary discharge the secondary battery to a designated reference state of charge (SoC) at a designated first current rate (C-rate), and when the secondary battery reaches the reference state of charge, secondary discharge the secondary battery to a designated peak negative voltage at a second current rate which is smaller than the first current rate. Accordingly, the present disclosure may improve the discharge efficiency of secondary batteries.

### CROSS-REFERENCE TO RELATED APPLICATION AND CLAIM OF PRIORITY

This application claims priority to Korean Patent Application No. 10-2023-0135769 filed on Oct. 12, 2023 in the Korean Intellectual Property Office (KIPO), the entire disclosure of which is incorporated by reference herein.

### BACKGROUND OF THE INVENTION

### 1. Field of the Invention

The present disclosure relates to a discharge device and a method for controlling discharge of the discharge device.

### 2. Description of the Related Art

A secondary battery is a battery that can be repeatedly charged and discharged. With rapid progress of information and communication, and display industries, the secondary battery has been widely applied to various portable telecommunication electronic devices such as a camcorder, a mobile phone, a tablet personal computer (PC), a laptop PC, etc. as a power source thereof. Recently, a battery pack including the secondary battery has also been developed as a power source of an eco-friendly automobile such as an electric vehicle.

The secondary battery may include, for example, a lithium secondary battery, a nickel-cadmium battery, a nickel-hydrogen battery and the like. Among the secondary batteries, the lithium secondary battery has a high operating voltage and a high energy density per unit weight, and is advantageous in terms of a charging speed and light weight. In this regard, the lithium secondary battery has been actively developed and used in various fields.

Meanwhile, when repeatedly charging and discharging the secondary battery more than a predetermined number of times, the performance thereof may be greatly decreased. In other words, the secondary battery may not be used permanently, and have a limitation in lifetime thereof. To secure the safety, it is necessary for a secondary battery that has reached the end of its lifetime (hereinafter referred to as a waste battery) to completely discharge the remaining energy, i.e., the previously charged power, before disposal (or recycle/reuse).

Therefore, a method capable of efficiently discharging the power remaining in the waste battery (i.e., residual energy) before disposing the waste battery is required.

### SUMMARY OF THE INVENTION

According to an aspect, it is an object of the present disclosure to provide a discharge device capable of efficiently (or effectively) discharging a secondary battery and a method for controlling discharge of the discharge device.

According to another aspect, it is another object of the present disclosure to provide a discharge device with improved stability against discharging of a secondary battery and a method for controlling discharge of the discharge device.

To achieve the above object, according to an aspect of the present disclosure, there is provided a discharge device including: a connection member configured to connect the discharge device and a secondary battery; a discharge module configured to discharge the secondary battery connected thereto through the connection member; and a control module configured to, when discharge of the secondary battery is requested, control the discharge module so as to primary discharge the secondary battery to a designated reference state of charge (SoC) at a designated first current rate (C-rate), and when the secondary battery reaches the reference state of charge, secondary discharge the secondary battery to a designated peak negative voltage at a second current rate which is smaller than the first current rate.

According to an embodiment, the discharge device may further include a voltage sensor configured to measure a voltage of the secondary battery and a current sensor configured to measure a current thereof, wherein the control module may control the discharge module so as to: check a state of charge of the secondary battery based on the voltage and current measured through the voltage sensor and the current sensor; and perform the primary discharge when the state of charge of the secondary battery exceeds the reference state of charge, and perform the secondary discharge when the state of charge of the secondary battery is the reference state of charge or less.

According to an embodiment, the discharge device may further include a switch module positioned between the connection member and the discharge module, wherein the control module may turn off the switch module if the voltage of the secondary battery reaches the peak negative voltage.

According to an embodiment, the discharge device may further include a temperature sensor configured to measure a temperature of the secondary battery, wherein the control module may be configured to: measure a first temperature through the temperature sensor during performing the primary discharge, and reduce the first current rate by a designated magnitude when the measured first temperature is a designated first reference temperature or higher.

According to an embodiment, the control module may be configured to: measure a second temperature through the temperature sensor during performing the secondary discharge, and reduce the second current rate by a designated magnitude when the measured second temperature a designated second reference temperature or higher.

According to an embodiment, the first current rate may have a range of 0.3 or more and 1.5 or less.

According to an embodiment, the second current rate may have a range of 0.1 to 0.5.

According to an embodiment, the secondary battery may include battery cells, a battery module and a battery pack.

According to another aspect of the present disclosure, there is provided a method for controlling discharge of a discharge device, the method including: when discharge of a secondary battery connected to the discharge device is requested, primary discharging the secondary battery to a designated reference state of charge (SoC) at a designated first current rate (C-rate); and when the secondary battery reaches the reference state of charge, secondary discharging the secondary battery to a designated peak negative voltage at a second current rate which is smaller than the first current rate.

According to an embodiment, the method may further include: checking a state of charge of the secondary battery; determining whether the checked state of charge of the secondary battery exceeds the reference state of charge; controlling to proceed to the primary discharging step when the secondary battery exceeds the reference state of charge; and controlling to proceed to the secondary discharging step when the secondary battery is the reference state of charge or less.

According to an embodiment, the method may further include, if the voltage of the secondary battery reaches the peak negative voltage, opening the electrical connection between the secondary battery and the discharge device.

According to an embodiment, the method may further include: measuring a first temperature using a temperature sensor during performing the primary discharge; and reducing the first current rate by a designated magnitude when the measured first temperature is a designated first reference temperature or higher.

According to an embodiment, the method may further include: measuring a second temperature through the temperature sensor during performing the secondary discharge; and reducing the second current rate by a designated magnitude when the measured second temperature is a designated second reference temperature or higher.

According to an embodiment of the present disclosure, the discharge efficiency of the secondary battery may be improved. For example, the discharge time of the secondary battery may be reduced. In addition, the discharge safety of the secondary battery may be improved. Further, the secondary battery may be discharged in an eco-friendly manner.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram schematically illustrating the configuration of a discharge device for discharging a secondary battery according to an embodiment of the present disclosure;

FIG. 2A is a flowchart for describing a method for controlling discharge of a discharge device according to an embodiment of the present disclosure;

FIG. 2B is a flowchart for describing a method for controlling discharge of a discharge device according to another embodiment of the present disclosure;

FIG. 3 is a graph illustrating changes in voltage and temperature of the secondary battery depending on the magnitude of a second current rate according to an embodiment of the present disclosure; and

FIGS. 4A to 4C are graphs illustrating changes in voltage of the secondary battery during the secondary discharge according to an embodiment of the present disclosure.

### DETAILED DESCRIPTION OF THE INVENTION

Hereinafter, exemplary embodiments of the present disclosure will be described in detail (with reference to the accompanying drawings). However, these embodiments are merely an example, and the present disclosure is not limited to the specific embodiments described as the example.

Although the terms first, second, etc. are used to describe various elements, components and/or sections, it will be understood that these elements, components and/or sections are not limited by these terms. These terms are merely used to distinguish one element, component or section from other elements, components or sections. Accordingly, it will be understood that the first element, first component, or first section mentioned below may also be the second element, second component, or second section within the technical spirit of the present disclosure.

Terms used herein are for the purpose of describing particular embodiments only and are not intended to limit the present disclosure thereto. As used herein, singular forms are intended to include the plural forms as well, unless the context clearly indicates otherwise. The terms “comprises” and/or “made of” used herein in relation to the components, steps, operations and/or elements do not preclude the presence or addition of one or more other components, steps, operations and/or elements other than those mentioned.

Unless otherwise defined, all terms (including technical and scientific terms) used herein have the same meaning as commonly understood by one of ordinary skill in the art to which the present disclosure pertains. Terms, such as those defined in commonly used dictionaries, are not to be construed in an idealized or overly formal sense unless expressly so defined herein.

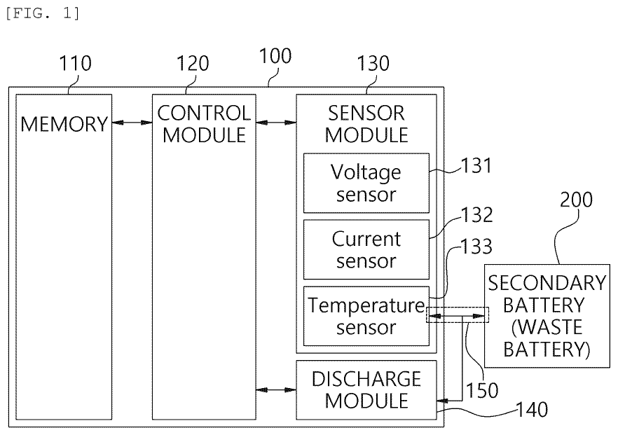

FIG. 1 is a block diagram schematically illustrating the configuration of a discharge device for discharging a secondary battery according to an embodiment of the present disclosure.

Referring to FIG. 1, a discharge device 100 according to an embodiment of the present disclosure may discharge a secondary battery 200.

According to an embodiment, the secondary battery 200 may be a secondary battery that has reached the end of its lifetime and is awaiting the disposal (or recycle). For example, the secondary battery 200 may include a waste battery for a vehicle, which was used in an eco-friendly vehicle (such as an electric vehicle, hydrogen vehicle, etc.) and then recovered for various reasons (such as inspection, repair, expiration, accident, vehicle disposal, etc.). According to an embodiment, the secondary battery 200 may include battery cells, a battery module or battery pack. The battery module may include N (N≥2) battery cells and battery manufacturer's battery management system (BMS) mounted by a battery manufacturer at the time of manufacturing the battery for a vehicle.

According to an embodiment, the discharge device 100 may include a memory 110, a control module 120, a sensor module 130, a discharge module 140, and a connection member 150.

The connection member 150 may electrically connect the secondary battery 200 and the discharge device 100. The connection member 150 may include a plurality of cables that can be connected (or fastened) to a positive electrode terminal (+) and a negative electrode terminal (−) of the secondary battery 200. In addition, the connection member 150 may include an extension cable (not shown) extending from the temperature sensor 133. When measuring a temperature of the secondary battery 200, one end (e.g., a side opposite to the side connected to the temperature sensor 133) of the extension cable (not shown) may be positioned on one side of the secondary battery 200 (or positioned around the secondary battery 200).

The discharge module 140 may discharge the secondary battery 200 under the control of the control module 120. For example, the discharge module 140 may completely remove (fully discharge) a power of the secondary battery 200 connected thereto through the connection member 150. According to an embodiment, the discharge module 140 may discharge the secondary battery 200 in two phases. For example, the discharge module 140 may discharge (primary discharge) the secondary battery 200 at a first current rate (C-rate) to a designated reference state of charge (SoC), and when the secondary battery reaches the reference state of charge, then may discharge (secondary discharge) the secondary battery 200 to the designated peak negative voltage at a second current rate which is smaller than the first current rate. The discharge module 140 may be a direct current-direct current (DC-DC) converter.

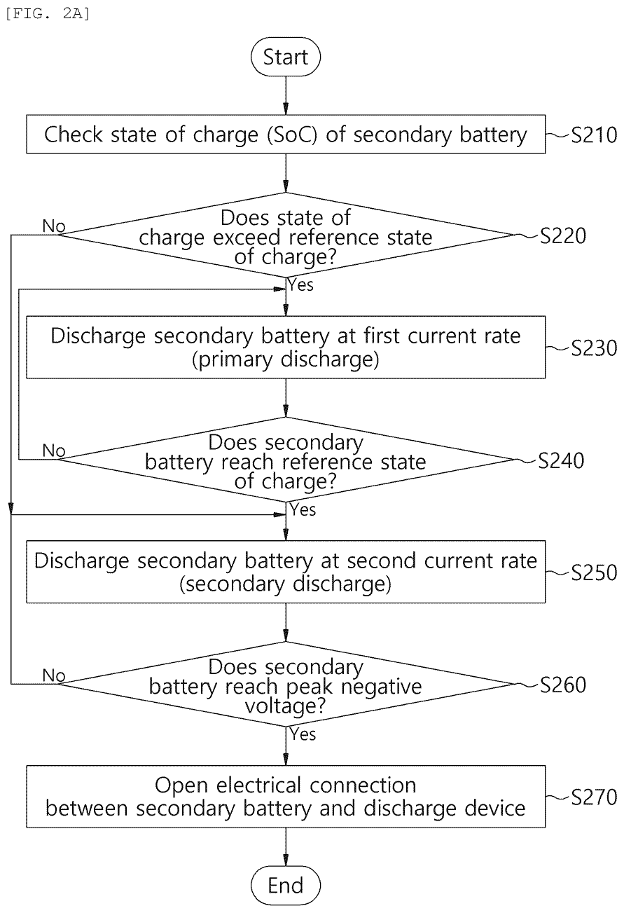

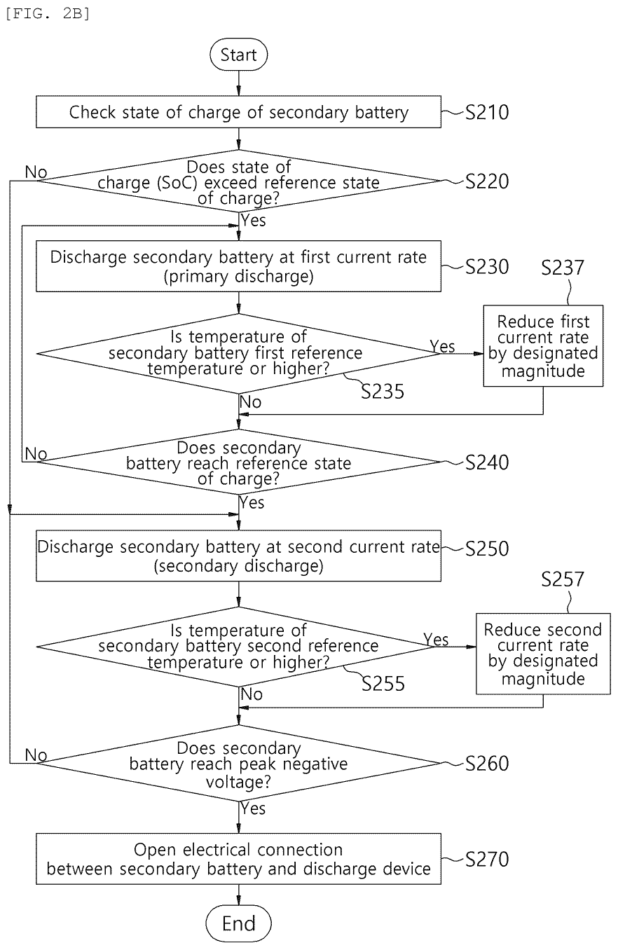

The sensor module 130 may measure the state of the secondary battery 200. The sensor module 130 may include a voltage sensor 131 configured to measure a voltage of the secondary battery 200, a current sensor 132 configured to measure a current of the secondary battery 200, and temperature sensor 133 configured to measure a temperature of the secondary battery 200. Meanwhile, as the embodiment shown in FIG. 2A which will be described below, if the temperature of the secondary battery 200 is not considered, the temperature sensor 133 may not be included in the discharge device 100.

The control module 120 may control an operation of the discharge device 100. For example, when a request to discharge the secondary battery 200 is detected, the control module 120 may control the discharge module 140 so as to primary discharge the secondary battery 200 to the reference state of charge at the first current rate, and when the secondary battery reaches the reference state of charge, then secondary discharge the secondary battery 200 to the peak negative voltage at the second current rate which is smaller than the first current rate. Here, the reason for reducing the magnitude of the current rate during the secondary discharge is that an increase in the temperature of the secondary battery 200 is not large even when performing the primary discharge at a high current rate, but when performing the secondary discharge at a high current rate, the increase in the temperature is large, which will be described in detail below with reference to FIG. 2A.

Meanwhile, the control module 120 may detect the temperature of the secondary battery 200 (or the surrounding temperature of the secondary battery 200) through the temperature sensor 133 during the primary or secondary discharge, and adjust the first current rate and/or the second current rate based on the detected temperature, which will be described in detail below with reference to FIG. 2B.

The memory 110 may store a program that controls a procedure for discharging in the discharge device 100. In addition, the memory 110 may store information necessary to control the procedure for discharging in the discharge device 100. For example, the memory 110 may store information such as the reference state of charge, peak negative voltage, first reference temperature, second reference temperature, third reference temperature, and/or fourth reference temperature.

Meanwhile, although not shown in the drawings, the discharge device 100 may further include a switch module for controlling (e.g., switching) the electrical connection with the secondary battery 200. The switch module may be positioned between the discharge module 140 and the connection member 150. When including the switch module, the control module 120 may turn on the switch module when the connection of the secondary battery 200 is detected. Alternatively, the switch module may basically remain in an on state. In addition, the control module 120 may turn off the switch module when the voltage of the secondary battery 200 reaches the peak negative voltage during performing the secondary discharge. That is, when the voltage of the secondary battery 200 reaches the peak negative voltage, the control module 120 may open the electrical connection between the secondary battery 200 and the discharge device 100.

FIG. 2A is a flowchart for describing a method for controlling discharge of a discharge device according to an embodiment of the present disclosure.

Referring to FIG. 2A, a discharge control method 10 of the discharge device according to an embodiment of the present disclosure may include a step of checking the state of charge (SoC) of the secondary battery (S210). For example, when the secondary battery 200 is connected to the discharge module through the connection member 150, the control module 120 of the discharge device 100 may measure the voltage and/or current of the secondary battery 200 through the sensor module 130 to check the state of charge of the secondary battery 200.

The discharge control method 10 may include a step of determining whether the state of charge exceeds a designated reference state of charge (S220). The reference state of charge may be set within a range of 0% to 10%, or specifically 0% to 5%, or more specifically 0% to 3%.

When the checked state of charge does not exceed the reference state of charge, the discharge control method 10 may proceed to a step S250, which will be described below. On the other hand, when the checked state of charge exceeds the reference state of charge, the discharge control method 10 may proceed to a step of discharging the secondary battery at a first current rate (hereinafter, primary discharge) (S230). The control module 120 of the discharge device 100 may control the discharge module 140 so as to discharge the secondary battery 200 at a first current rate. The first current rate may be set to one value (e.g., 1.0) within a range of 0.3 to 1.5 (i.e., 0.3 or more and 1.5 or less), or specifically 0.7 to 1.2, or more specifically 0.9 to 1.1.

The discharge control method 10 may include a step of determining whether the secondary battery reaches the reference state of charge (S240). For example, the control module 120 of the discharge device 100 may determine whether the state of charge of the secondary battery 200 reaches the reference state of charge by measuring a voltage and/or current of the secondary battery 200 through the sensor module 130.

When the state of charge of the secondary battery 200 does not reach the reference state of charge, the discharge control method 10 may return to the step S230. On the other hand, when the state of charge of the secondary battery 200 reaches the reference state of charge, the discharge control method 10 may proceed to a step of discharging the secondary battery at a second current rate (hereinafter, secondary discharge) (S250). The control module 120 of the discharge device 100 may control the discharge module 140 so as to change the current rate for discharging the secondary battery 200 to a second current rate which is smaller than the first current rate, and discharge the secondary battery 200 at the second current rate. The second current rate may be set to one value (e.g., 0.3) within a range of 0.1 to 0.5 (i.e., 0.1 or more and 0.5 or less), or specifically between 0.2 and 0.5, or more specifically between 0.3 and 0.5.

The discharge control method 10 may include a step of determining whether the voltage of the secondary battery reaches a designated peak negative voltage (S260). For example, the control module 120 of the discharge device 100 may measure the voltage of the secondary battery 200 through the voltage sensor 131 and compare the measured voltage with a peak negative voltage. The peak negative voltage may be set within a range of −1.5 to −0.4 V, or specifically −1.0 to −0.6 V, or more specifically −0.9 to −0.7 V.

When the voltage of the secondary battery does not reach the designated peak negative voltage, the discharge control method 10 may return to the step S250. On the other hand, when the voltage of the secondary battery reaches the designated peak negative voltage, the discharge control method 10 may proceed to a step of opening the electrical connection between the secondary battery and the discharge device (S270). For example, the control module 120 of the discharge device 100 may open a switch module (not shown) positioned between the connection member 150 and the discharge module 140. As another example, the control module 120 may guide an operator to remove the connection member 150 from the secondary battery 200 by outputting a designated sound effect through an audio device (e.g., speaker) (not shown).

In the discharge method according to an embodiment of the present disclosure, as the discharging procedure is stopped after discharging the secondary battery to the peak negative voltage, an open circuit voltage may converge to 0 V. Accordingly, the discharge method of the present disclosure does not require a procedure for short circuiting the battery from outside, which had to additionally perform in the conventional method to remove the open circuit voltage. Thereby, the discharge method of the present disclosure may greatly reduce the discharging time of the secondary battery. Further, in the discharge method of the present disclosure, by reducing the magnitude of the second current rate compared to the first current rate, it is possible to improve stability against heat generation during the secondary discharge in which the secondary battery is over-discharged to the peak negative voltage. In addition, the discharge method according to the present disclosure may discharge the secondary battery in an eco-friendly manner without using salt water.

Meanwhile, as such, in steps S210 and S220 above, it has been described that the state of charge of the secondary battery is checked and the primary discharge or secondary discharge is performed by comparing the checked SOC with the reference state of charge. However, according to another embodiment, the discharge control method 10 may check the voltage of the secondary battery and compare the checked SOC with a reference voltage (e.g., 0 to 3 V or a voltage corresponding to a “0%” state of charge (SOC)). As another example, the steps S210 and S220 may be omitted. For example, the discharge control method 10 may perform the step S230 when connection of the secondary battery is detected.

In addition, the discharge control method 10 may further include a step of measuring a voltage of the secondary battery 200 when the connection of the secondary battery 200 is detected and determining whether the measured voltage is less than (or not more than) a designated voltage (e.g., 1000 V). The designated voltage may be the maximum voltage supported by the discharge device 100. This is intended to prevent the discharge device 100 from being damaged due to an excessive voltage.

FIG. 2B is a flowchart for describing a method for controlling discharge of a discharge device according to another embodiment of the present disclosure.

Referring to FIG. 2B, a discharge control method 20 of the discharge device according to another embodiment of the present disclosure is similar to the discharge control method 10 shown in FIG. 2A. Hereinafter, configurations (e.g., S210, S220, S230, S240, S250, S260 and S270) overlapped with the discharge control method 10 shown in FIG. 2A will not be described.

According to an embodiment, the discharge control method 20 may measure a temperature of the secondary battery and adjust the first current rate and the second current rate based on the measured temperature. For example, the discharge control method 20 may measure a temperature of the secondary battery during performing the primary discharge, and adjust (e.g., maintain or decrease) the first current rate based on the measured temperature. In addition, the discharge control method 20 may measure a temperature of the secondary battery during performing the secondary discharge and adjust (e.g., maintain or decrease) the second current rate based on the measured temperature.

Specifically, the discharge control method 20 may further include, after the step S230 of discharging the secondary battery at a first current rate, a step of determining whether a temperature of the secondary battery is a designated first reference temperature (e.g., 80° C.) or higher (S235). For example, the control module 120 may measure a temperature (or ambient temperature) of the secondary battery 200 through the temperature sensor 133 and determine whether the measured temperature is the first reference temperature or higher. The temperature sensor 133 may be located on one side of the secondary battery 200 or around the secondary battery 200 when connecting the discharge device 100 and the secondary battery 200 to discharge the secondary battery 200.

When the temperature of the secondary battery is less than the first reference temperature, the discharge control method 20 may proceed to the step S240. On the other hand, when the temperature of the secondary battery is the first reference temperature or higher, the discharge control method 20 may proceed to a step of reducing the first current rate by a designated magnitude (e.g., 0.2 C-rate) (S237). For example, when the temperature of the secondary battery is increased to the first reference temperature or higher, the control module 120 may control the discharge module 140 to reduce the first current rate by the designated magnitude.

In addition, the discharge control method 20 may further include, after the step S250 of discharging the secondary battery at a second current rate, a step of determining whether the temperature of the secondary battery is a designated second reference temperature (e.g., 80° C.) or higher (S255). For example, the control module 120 may measure a temperature (or ambient temperature) of the secondary battery 200 through the temperature sensor 133 and determine whether the measured temperature is the second reference temperature or higher.

When the temperature of the secondary battery is less than the second reference temperature, the discharge control method 20 may proceed to the step S260. On the other hand, when the temperature of the secondary battery is the second reference temperature or higher, the discharge control method 20 may proceed to a step of reducing the second current rate by a designated magnitude (e.g., 0.2 C-rate) (S257). For example, when the temperature of the secondary battery 200 is increased to the second reference temperature or higher, the control module 120 may control the discharge module 140 to reduce the second current rate by the designated magnitude.

The second reference temperature may be the same as or different from the first reference temperature. In addition, the magnitude by which the first current rate is reduced in the step S237 may be the same as or different from the magnitude by which the second current rate is reduced in the step S257.

Meanwhile, in FIG. 2B, it has been disclosed and described that the temperature of the secondary battery is checked during performing the primary discharge and secondary discharge, and the first and second current rates are adjusted based on the checked temperature. However, according to another embodiment, the discharge control method 20 may also check the temperature of the secondary battery only during performing the primary discharge or during performing the secondary discharge, and adjust the first current rate or the second current rate based on the checked temperature.

The discharge control method 20 may further improve (e.g., enhance) the stability against discharge of the secondary battery by checking the temperature of the secondary battery during the primary discharge and/or secondary discharge, and appropriately adjusting the current rate based on the checked temperature. For example, the discharge control method 20 may prevent unintentional heat generation from occurring due to various causes, even though the magnitudes of the first and second current rates are set so as to prevent an occurrence of excessive heat generation.

Meanwhile, in FIG. 2B, only an example of reducing the first current rate and the second current rate depending on the temperature of the secondary battery during performing the primary discharge and secondary discharge has been disclosed and described. However, according to another embodiment, when the temperature of the secondary battery is lower than a third reference temperature (set to a value lower than the first reference temperature) or a fourth reference temperature (set to a value lower than the second reference temperature), the discharge control method may further include a step of increasing the first current rate or the second current rate by a designated magnitude to prevent an occurrence of problems due to heat generation. For example, the discharge control method may further include a step of increasing the first current rate when the temperature of the secondary battery is lower than the third reference temperature and/or increasing the second current rate when the temperature of the secondary battery is lower than the fourth reference temperature. Through this, the discharge control method 20 may increase the magnitude of the current rate within a range that does not generate excessive heat. That is, the present disclosure may prevent the overall discharge from being prolonged which is caused by setting the current rate too low.

Hereinafter, embodiments of the present invention will be further described with reference to specific experimental examples. However, the following examples and comparative examples included in the experimental examples are only given for illustrating the present invention and those skilled in the art will obviously understand that various alterations and modifications are possible within the scope and spirit of the present invention. Such alterations and modifications are duly included in the appended claims.

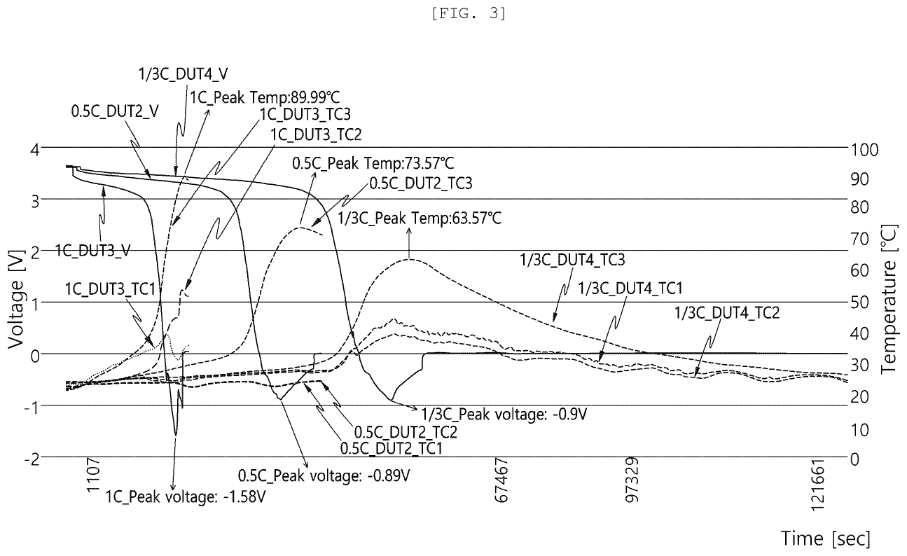

FIG. 3 is a graph illustrating changes in voltage and temperature of the secondary battery depending on the magnitude of a second current rate according to an embodiment of the present disclosure.

Referring to FIG. 3, in the secondary battery according to an embodiment of the present disclosure, a peak voltage, peak temperature, and peak voltage arrival time may vary depending on the magnitude of the second current rate during the secondary discharge. For example, according to the example shown in FIG. 3, the peak voltage, peak temperature, and peak voltage arrival time depending on the magnitude of the second current rate are as described in <Table 1> below.

TABLE 1

| Item | 1.0 C | ½ C | ⅓ C |
|---|---|---|---|
| Peak voltage (negative | −1.58 | −0.89 | −0.9 |
| voltage) (V) | | | |
| Peak temperature (° C.) | 89.99 | 73.57 | 63.57 |
| Peak voltage arrival time | 1,622 | 3,189 | 5,082 |
| (sec) | | | |

Referring to <Table 1> above, when the magnitude of the second current rate is large (e.g., 1.0 C), the peak voltage arrival time is reduced (i.e., the secondary discharge time is reduced), but the peak temperature is increased (i.e., the stability is decreased). On the other hand, when the magnitude of the second current rate is small (e.g., ⅓ C), the peak temperature is decreased, but the peak voltage arrival time is increased.

In one embodiment of the present disclosure, the magnitude of the second current rate may be determined by considering the peak voltage, peak temperature, and peak voltage arrival time of the secondary battery depending on the magnitude of the second current rate. That is, the present disclosure may determine the magnitude of the second current rate by considering the discharge time (e.g., the peak voltage and peak voltage arrival time) and the stability (e.g., the peak temperature). For example, in the case of <Table 1> above, the magnitude of the second current rate may be determined to be ½ (=0.5) C.

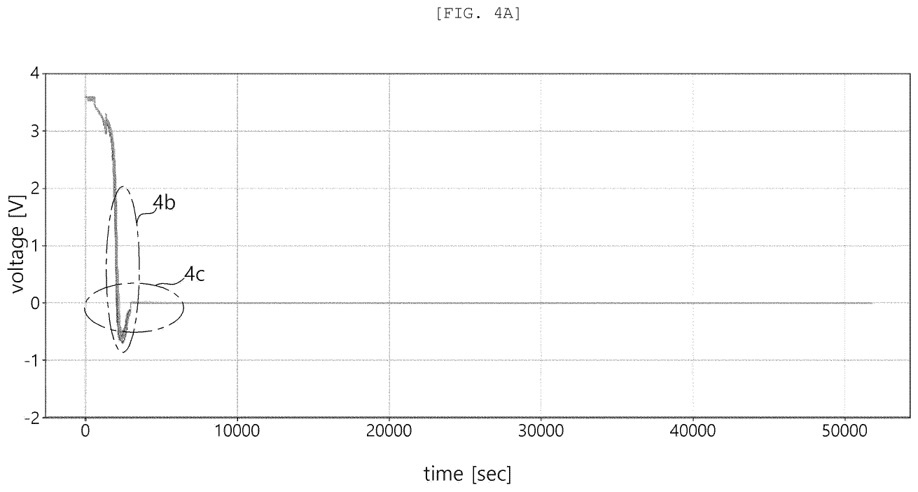

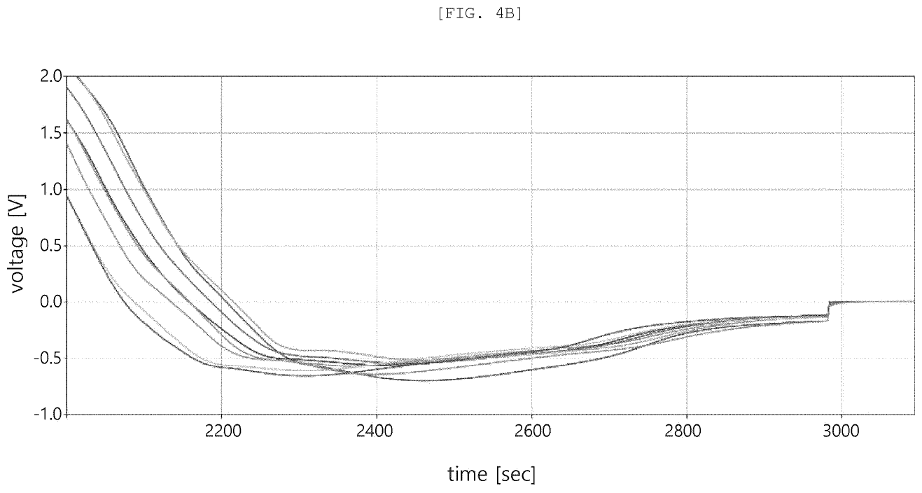

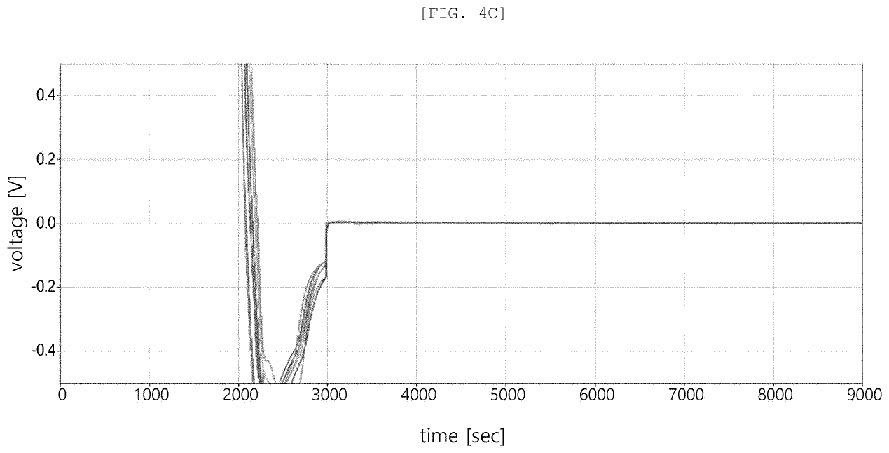

FIGS. 4A, 4B and 4C are graphs illustrating changes in voltage of the secondary battery during the secondary discharge according to an embodiment of the present disclosure.

Referring to FIGS. 4A to 4C, in one embodiment of the present disclosure, it is possible to discharge the secondary battery through the discharge device. For example, the discharge device primary discharges a secondary battery with a 30% state of charge (SoC) to a 0% state of charge (SoC) at a current rate of 1 C, and secondary discharges the secondary battery from the 0% state of charge (SoC) (about 3.6 V) to the peak negative voltage (about 0.7 V) at a current rate of 0.5 C, then the discharge procedure may be stopped (e.g., by opening the circuit). As the graphs shown in FIGS. 4A to 4C, the voltage of the secondary battery may be over-discharged to the peak negative voltage, and then rebounded to about 0 V by the open circuit voltage (OCV) rebounding phenomenon. That is, in the discharge method of the discharge device according to an embodiment of the present disclosure, as the discharging procedure is stopped after discharging the secondary battery to the peak negative voltage, an open circuit voltage may converge to 0 V. Accordingly, the discharge method of the present disclosure does not require a procedure for short circuiting the battery from outside, which had to additionally perform in the conventional method to remove the open circuit voltage. Thereby, the discharge method of the present disclosure may greatly reduce the discharging time of the secondary battery.

The contents described above are merely an example to which the principles of the present disclosure are applied, and other configurations may be further included in the present disclosure without departing from the scope of the present invention.

What is claimed is:

1. A discharge device comprising:
a connection member configured to connect the discharge device and a secondary battery;
a discharge module configured to discharge the secondary battery connected thereto through the connection member; and
a control module configured to, when discharge of the secondary battery is requested, control the discharge module so as to primary discharge the secondary battery to a designated reference state of charge (SoC) at a designated first current rate (C-rate), and when the secondary battery reaches the reference state of charge, secondary discharge the secondary battery to a designated peak negative voltage at a second current rate which is smaller than the first current rate.

2. The discharge device according to claim 1, further comprising a voltage sensor configured to measure a voltage of the secondary battery and a current sensor configured to measure a current thereof,
wherein the control module controls the discharge module so as to:
check a state of charge of the secondary battery based on the voltage and current measured through the voltage sensor and the current sensor; and
perform the primary discharge when the state of charge of the secondary battery exceeds the reference state of charge, and perform the secondary discharge when the state of charge of the secondary battery is the reference state of charge or less.

3. The discharge device according to claim 1, further comprising a switch module positioned between the connection member and the discharge module,
wherein the control module turns off the switch module if the voltage of the secondary battery reaches the peak negative voltage.

4. The discharge device according to claim 1, further comprising a temperature sensor configured to measure a temperature of the secondary battery,
wherein the control module is configured to:
measure a first temperature through the temperature sensor during performing the primary discharge, and
reduce the first current rate by a designated magnitude when the measured first temperature is a designated first reference temperature or higher.

5. The discharge device according to claim 4, wherein the control module is configured to:
measure a second temperature through the temperature sensor during performing the secondary discharge, and
reduce the second current rate by a designated magnitude when the measured second temperature a designated second reference temperature or higher.

6. The discharge device according to claim 1, wherein the first current rate has a range of 0.3 or more and 1.5 or less.

7. The discharge device according to claim 1, wherein the second current rate has a range of 0.1 to 0.5.

8. The discharge device according to claim 1, wherein the secondary battery comprises battery cells, a battery module and a battery pack.

9. A method for controlling discharge of a discharge device, the method comprising:
when discharge of a secondary battery connected to the discharge device is requested, primary discharging the secondary battery to a designated reference state of charge (SoC) at a designated first current rate (C-rate); and
when the secondary battery reaches the reference state of charge, secondary discharging the secondary battery to a designated peak negative voltage at a second current rate which is smaller than the first current rate.

10. The method according to claim 9, further comprising:
checking a state of charge of the secondary battery;
determining whether the checked state of charge of the secondary battery exceeds the reference state of charge;
controlling to proceed to the primary discharging step when the secondary battery exceeds the reference state of charge; and
controlling to proceed to the secondary discharging step when the secondary battery is the reference state of charge or less.

11. The method according to claim 9, further comprising, if the voltage of the secondary battery reaches the peak negative voltage, opening the electrical connection between the secondary battery and the discharge device.

12. The method according to claim 9, further comprising:
measuring a first temperature using a temperature sensor during performing the primary discharge; and
reducing the first current rate by a designated magnitude when the measured first temperature is a designated first reference temperature or higher.

13. The method according to claim 12, further comprising:
measuring a second temperature through the temperature sensor during performing the secondary discharge; and
reducing the second current rate by a designated magnitude when the measured second temperature is a designated second reference temperature or higher.
